(19) United States
(12) Patent Application Publication
(10) Pub. No.: US 2020/0119303 A1
(43) Pub. Date: Apr. 16, 2020

(54) MULTILAYER DISPLAY WITH INTEGRATED EDGE COVERING

(71) Applicant: Google LLC, Mountain View, CA (US)

(72) Inventors: Chu-Chun Lo, New Taipei City (TW); Chun Tseng, Taipei (TW); Mike Liu, Taipei (TW)

(21) Appl. No.: 16/157,361

(22) Filed: Oct. 11, 2018

(51) Int. Cl. H01L 51/52; H05K 5/00; H05K 5/03; H01L 27/32; H01L 51/56

(52) U.S. Cl. CPC H01L 51/5246; H05K 5/0017; H05K 5/03; H01L 51/5253; H01L 51/56; H01L 27/3244; H01L 27/323

(57) ABSTRACT

A display that is suitable for use with a mobile computing device is disclosed. The display includes multiple layers that are bonded in a stack that has side surfaces. Operation of the display may be negatively affected if the side surfaces are exposed to liquids or debris. Accordingly, a film affixed at, or close to, the top of the stack is folded around the side surfaces and attached to a back surface of the stack to cover the side surfaces. This covering can also block light if it is colored, and may help bind layers of the stack together to prevent delamination.

### FIELD OF THE DISCLOSURE

The present disclosure relates to a display for a mobile computing device and more specifically, to a display that includes multiple layers with one of the layers extending past and folded over edges of the other layers.

### BACKGROUND

The dimensions of displays in mobile computing devices are becoming larger to meet consumer expectations and demands. It is desirable that as displays are enlarged, the overall dimensions of mobile computing devices remain the same to allow for convenient handheld operation and portability. To meet this goal, the edges of a display can be arranged closer to the edges of the mobile computing device. The edges of the mobile computing device, however, are susceptible to exposure and stress, and the close arrangement leaves less space for shielding and protecting the edges of the display. Accordingly, new displays for mobile computing devices are needed.

### SUMMARY

In one general aspect, the present disclosure describes a display. The display includes a cover glass and a display module. The display module includes multiple layers that are aligned and adhered together to define a plurality of (e.g., four) side surfaces. The display also includes a film that has a transparent central portion and a plurality of (e.g., four) edge portions. The transparent central portion is affixed between the cover glass and a front surface of the display module. The edge portions are each folded around one of the side surfaces and affixed to the back surface of the display module.

In another general aspect, the present disclosure describes a method for fabricating a display. The method includes attaching a film to a front surface of an organic light emitting diode (OLED) display module using optically clear adhesive (OCA) so that edge portions of the film extend past side surfaces of the OLED display module. An adhesive film is affixed to the edge portions of the film and the edge portions of the film are folded around the side surfaces of the OLED display module and flush with the back surface of the OLED display module. The folded edge portions are then bonded to the back surface of the OLED display module using the adhesive film so that the side surfaces are covered by the film.

In another general aspect, the present disclosure describes a mobile computing device. The mobile computing device includes a bezel that defines sides of the mobile computing device and a cover glass that defines a front surface of the mobile computing device. The mobile computing device also includes a display module that is affixed between the cover glass and the bezel. The display module includes multiple layers that are laminated together to define a front surface, a back surface, and side surfaces of the display module. The display module also includes a film that has a transparent central portion affixed between the front surface of the display module and the cover glass. The film has edge portions that are folded around the side surfaces of the display module and that are affixed to the back surface of the display module.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 illustrates a mobile computing device according to an embodiment of the present disclosure.

FIG. 2 illustrates a side section view of a mobile computing device including a display module according to an embodiment of the present disclosure.

FIG. 3 illustrates a front view of a film for a display with different regions of the film indicated.

FIG. 4A illustrates a front view of a film for a display with edge portions that facilitate folding.

FIG. 4B graphically illustrates the steps of folding the film of FIG. 4A for a display according to an embodiment of the present disclosure.

FIG. 5 illustrates a side section view of the film along the cut plane indicated in FIG. 4A.

FIG. 6 illustrates a side section view of a display according to a first embodiment of the present disclosure.

FIG. 7 illustrates a side section view of a display according to a second embodiment of the present disclosure.

FIG. 8 is a flow chart of a method for fabricating a display according to a possible embodiment of the present disclosure.

FIG. 9 shows an example of a computer device and a mobile computer device that can be used to implement the techniques described here.

The components in the drawings are not necessarily to scale relative to each other. Like reference numerals designate corresponding parts throughout the several views.

### DETAILED DESCRIPTION

The present disclosure embraces a display module (i.e., display) for a mobile computing device. The display has multiple layers. One of the multiple layers is used to cover the edges of the display. The covering can protect the edges of the display from contact with liquids or other contaminants (e.g., debris). Additionally, the covering may block light emitted from the edges of the display from leaking out of the mobile computing device. Finally, the covering may help prevent the multiple layers from delaminating (e.g., one or more layers separating and/or peeling) if, for example, the mobile computing device experiences an impact (e.g., is dropped).

When the disclosed display is used in a mobile computing device, other edge covering/protecting structures may not be required. Eliminating these other structures can allow the edges of the display to be positioned closer to the edges of the mobile computing device. As a result, the display area of a mobile computing device may be increased without increasing the overall dimensions of the mobile computing device.

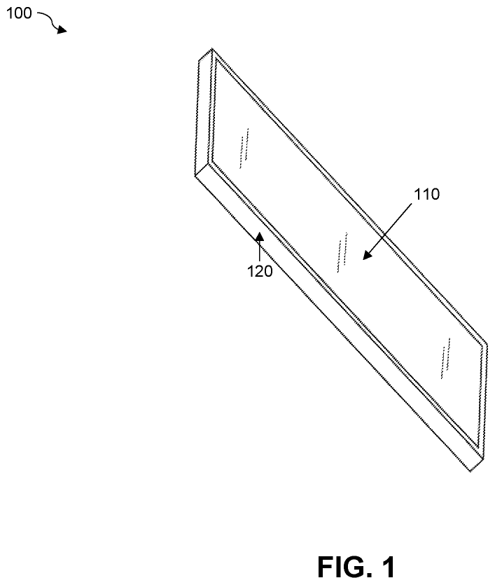

FIG. 1 illustrates a mobile computing device according to an embodiment of the present disclosure. A front surface of the mobile computing device 100 is defined by a cover glass 110. A bezel 120 surrounds the cover glass 110 and defines side surfaces (i.e., sides) of the mobile computing device 100 and defines a back surface (opposite to the front surface—not shown) of the mobile computing device 100.

A display is situated within a volume defined by the cover glass 110 and the bezel 120 and during operation, the display projects visual information through the cover glass 110 to a user. The display area may be made larger by extending its edges towards the sides of the bezel 120. As the display's edges are extended towards the sides of the bezel, more of the cover glass must be used for display instead of support. This may result in supporting architectures that leave the display exposed to liquid and/or contaminants. For example, liquids and/or contaminants may reach the display through a gap formed between the cover glass 110 and the bezel 120. This gap may be very small (e.g., less than 0.1 millimeters) but may still allow liquids or containments to enter the volume defined by the cover glass 110 and the bezel 120 where the display is situated.

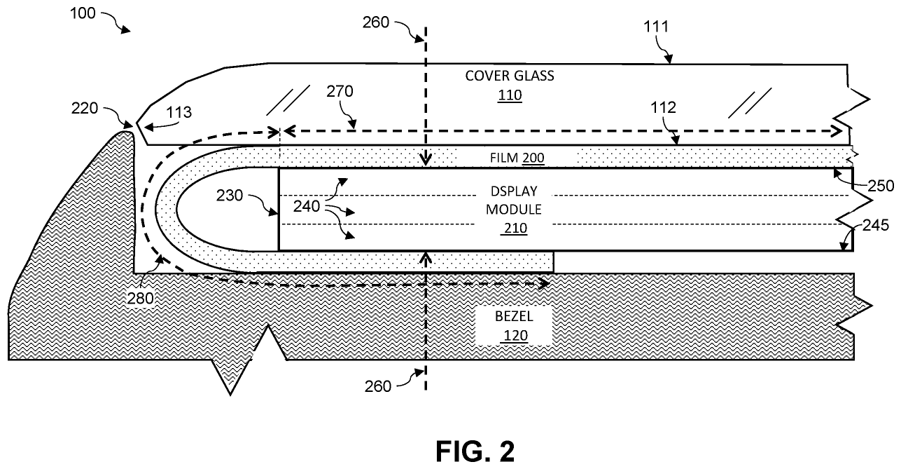

FIG. 2 illustrates a side section view of a portion of the mobile computing device 100 close to an edge 113 of the cover glass 110. In this example, no practical room (i.e., space, volume, etc.) exists for a supporting feature (i.e., ledge, shelf) in the bezel 120 to support the cover glass 110 at an edge 113. Instead, the cover glass 110 is affixed at its back surface 112 (i.e., opposite to a front surface 111) to the bezel 120 through a bonded stack that includes a display module 210 and a film 200. The film has properties that allow it to be folded (i.e., flexible), to seal against liquids and dust/debris (i.e., impervious), and to be viewed through (i.e., transparent).

A first portion (i.e., central portion) 270 of the film 200 is positioned between a front surface 250 of the display module 210 and the back surface 112 of the cover glass 110. A second portion (i.e., edge portion) 280 of the film 200 is folded (i.e., wrapped) around a side surface (i.e., side) 230 of the display module and into a position that is flush with (i.e., along the surface of) at least a portion of a back surface 245 of the display module 210.

The display module 210 includes layers 240. The layers may include layers for a particular function and layers for support and/or mechanical connection. The edge portion 280 of the film 200 covers the side 230 of the display module 210 so that the layers 240 are not exposed to liquids and/or contaminants. In other words, the edge portion 280 of the film 200 forms a barrier that is impermeable to the liquids and/or contaminants. Without the covering (i.e., seal, barrier, etc.) provided by the edge portion 280, liquids or contaminants (e.g., dust, debris, food particles, etc.) could pass through a gap 220 defined between the cover glass 110 and the bezel 120 and affect the electrical operation of one or more of the layers 240 of the display module 210 or affect the mechanical integrity (e.g., bonding) of one or more of the layers 240 of the display module 210. Additionally, when the film is affixed to the front surface 250 and the back surface 245 of the display module 210, the layers 240 may experience a compressive stress 260 (e.g., in an area adjacent to a side 230) that prevents the layers 240 from delaminating (e.g., as a result of an impact). In other words, when the display module has suffered a peel force, the film can provide a compressive stress by the side area of material elongation to avoid delamination.

The side section view of FIG. 2 may be any portion of the mobile computing device 100 close to an edge 113 of the cover glass 10. In other words, the side surface 230 of the display module 210 shown in FIG. 2 could be any side surface (e.g., a top side surface, a bottom side surface, a left side surface, a right side surface) of the display module.

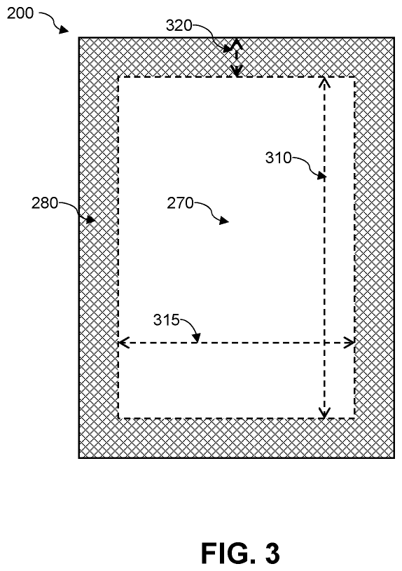

A front view of the film 200 as it appears before it is folded is shown in FIG. 3. The central portion of the film 270 is aligned with the display. Accordingly, the central portion 270 has a height 310 and a width 315 that correspond to the display area of display module 210. Additionally, the central portion 270 is transparent so the display may be viewed through the film 200. The edge portion 280 of the film 200 surrounds the central portion 270 and extends, by a width 320, to the edges of the film. The width 320 of the edge portion 280 may correspond to a height of the side surface 230 of the display module 210 (i.e., dimension between front surface 250 and back surface 245). The width 320 of the edge portion 280 may also correspond to the portion of the film that is positioned flush with the back surface 245 of the display. For example, the width 320 may be selected to cover an edge 230 of the display module 210 and to provide a bonding area between the back surface 245 of the display module and the bezel. The bonding area can affect the strength of the bond and can affect the compressive stress 260 (i.e., the force per unit area) resulting from the bond. In some embodiments, the edge portion 280 is colored opaque to prevent light from the edge 230 of the display module 210 from being transmitted into view of a user of the mobile device. For example, the edge portion 280 may be inked (or painted) black to block light from a side 230 of the display module 210 so that it does not propagate (i.e., escape, leak) through the cover glass 110 and/or through the gap 220.

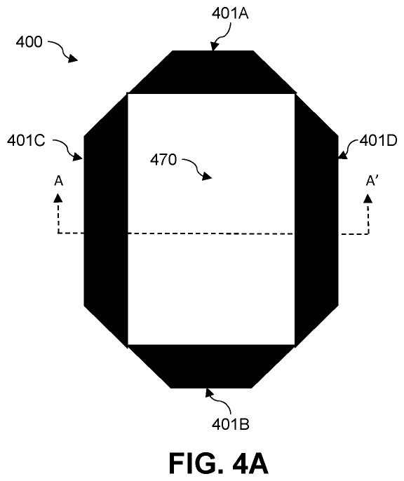

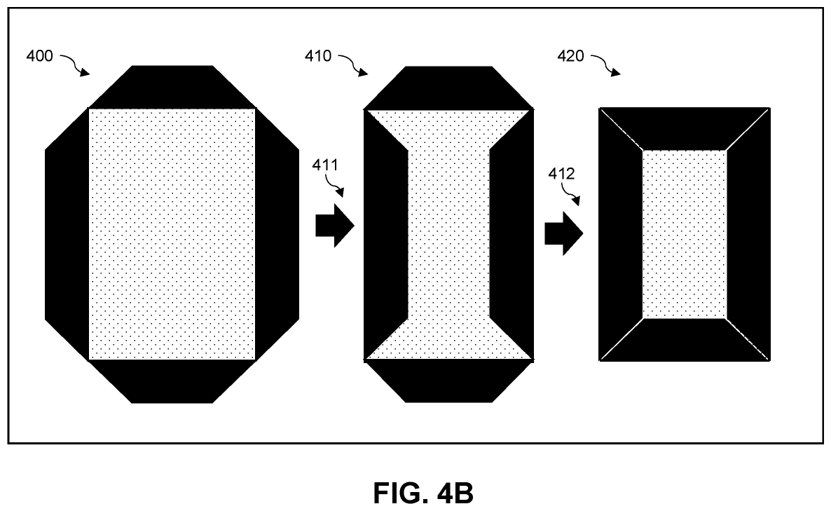

The film is typically shaped (e.g., cut) to facilitate folding multiple (e.g., four) edge portions around corresponding side surfaces of the display module 210. FIG. 4A illustrates a front view of a film 200 with four edge portions. The four edge portions may include a top edge portion 401A (e.g., to correspond with a top side surface of a display module); a bottom edge portion 401B (e.g., to correspond with a bottom side surface of a display module); a left edge portion 401C (e.g., to correspond with a left side surface of a display module); and a right edge portion 401D (e.g., to corresponds with a right side surface of a display module). The edge portions 401A, 401B, 401C, 401D may be opaque and as shown, each edge portion may have a trapezoidal shape. The trapezoidal edge portions can be arranged so that one of the edges of each trapezoidal edge portion defines an edge of the central portion 470 of the film 400. When shaped and arranged this way, the edge portions 401A, 401B, 401C, 401D may be folded without any overlap.

FIG. 4B graphically illustrates possible steps for folding the film of FIG. 4A. While not shown, the display module may be aligned with the central portion prior to the steps of folding. In a first step 411 of folding, the left edge portion 401C and the right edge portion 401D of the unfolded film 400 may be folded towards the central portion 470 to form a partially folded film 410. In a second step of folding 412, the top edge portion 401A and a bottom edge portion 401B may be folded towards the central portion to form a folded film 420. No edge portions in the folded film 420 overlap.

An aspect of the present disclosure is folding the film without overlap. Preventing overlap may be advantageous by providing a substantially flat surface for bonding the display module to the bezel. In general, the present disclosure embraces all film shapes, modifications (e.g., cuts), and/folding steps that prevent or mitigate edge portion overlap while providing cover and mechanical support to the display module. Accordingly, the present disclosure is not limited to the particular shape and folding process shown as examples in FIGS. 4A and 4B.

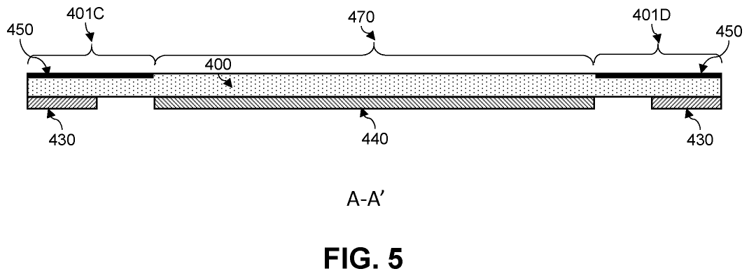

The folded edge portions may be held to the front surface 250 and the back surface 245 of the display module 210 in various ways. FIG. 5 illustrates a side section view of the film along the A-A′ cut plane indicated in FIG. 4A. The film 400 includes a transparent central portion 470 and a left edge portion 401C and a right edge portion 401D that are colored by ink 450 to be opaque. The film may be a thin (e.g., in the range of 0.03-0.1 millimeters (mm)) sheet of a polymer such as, but not limited to, polyethylene terephthalate (PET) or colorless polyimide (CPI).

For attachment (e.g., bonding) to a front surface 250 of the display module 210, a layer of optically clear adhesive (OCA) 440 may be applied to at least a portion of the central portion 470 of the film 470. The OCA may include a film (e.g., tape) or liquid type of adhesive. For example, a double-sided OCA tape may be applied to the central portion of the film 400.

For attachment (e.g., bonding) to a back surface 245 of the display module 210, an adhesive film 430 may be applied to at least a portion of the edge portions (i.e., the left and right edge portions as shown in this view) of the film. For example, a double sided tape 430 may applied to the edge portions. The tape need not be transparent because the edge portions of the film are attached (i.e., affixed) to the back surface 245 of the display module 210.

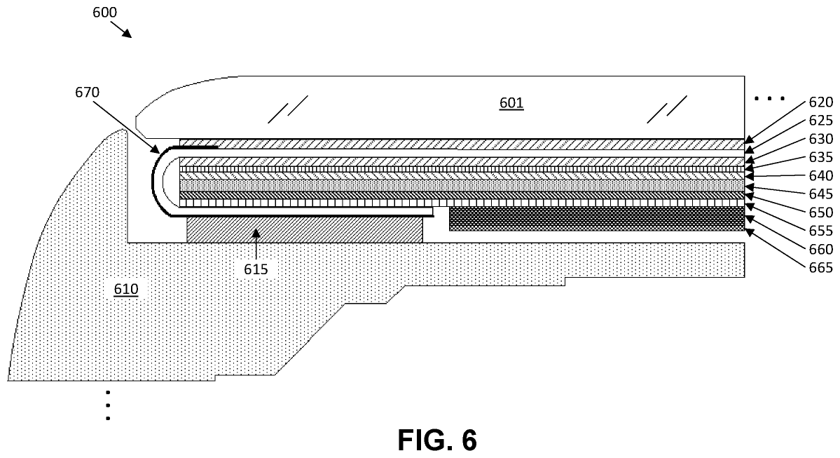

The principles described thus far may be embodied variously in a mobile computing device (e.g., laptop, tablet, smartphone). A detailed view of a first possible embodiment is shown in FIG. 6. FIG. 6 illustrates a side section view of a portion of a mobile computing device 600. The mobile computing device includes a cover glass 601, a bezel 610, and a display module.

The display module includes a touch sensor that includes a first touch-sensor layer 640 and a second touch-sensor layer 635. The display module also includes an organic light emitting diode (OLED) display that includes a first (i.e., back) OLED layer 655, a second (i.e., front) OLED layer 650, and a polarizer 645. The back OLED layer 655 is a substrate (e.g., polyimide substrate) onto which the active OLED elements, the controlling electronics (e.g., thin film transistors (TFT)) and traces are disposed. The front OLED layer 650 covers the active OLED elements (i.e., film OLED) to protect (i.e., isolate) them from oxygen and moisture. A sponge layer 660 (e.g., double-sided tape) and a layer of copper foil 665 provide covering for a portion of the second OLED layer of the display module. The sponge layer provides protection for the film OLED and absorbs mechanical stress.

The mobile computing device 600 also includes a film. A central portion of the film 625 is attached between the second touch-sensor layer 635 and the cover glass 601 using two layers of OCA 620,630. The edge portion 670 of the film is folded around the side surfaces of the display module and affixed to the first OLED layer 655. As shown, the edge portion 670 is colored opaque to block light. The cover glass, the film, and the layers of the display module are attached to the bezel 610 using a layer of adhesive 615 (e.g., double sided tape).

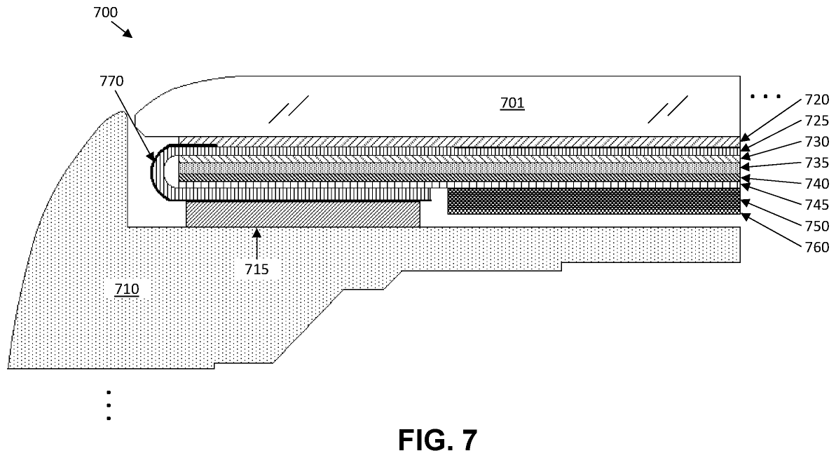

In another possible embodiment, an existing layer of the display module may be modified to function as the film. This approach may simplify fabrication and reduce size of the resulting assembly by eliminating the single purpose film. A detailed view of this embodiment is shown in FIG. 7. FIG. 7 illustrates a side section view of a portion of a mobile computing device 700. The mobile computing device includes a bezel 710, a cover glass 701, and layers of a display module affixed there between. The layers of the display module are laminated together. The layers include a font touch sensor layer 725 and a back touch sensor layer 730. The layers also include a polarizer 735 and two layers for an OLED display (i.e., a front layer of the OLED display 740, a back layer of the OLED display 745). The layers also include a sponge layer 750 (e.g., double sided tape) and a layer of copper foil 760. The cover glass is affixed to the layers using a layer of OCA 720. The cover glass 701 and layers are affixed to the bezel 710 using a layer of adhesive 715 (e.g., double-sided tape). A portion 770 of the front touch sensor layer 725 is folded around the sides of the layers and attached to the back layer of the OLED display 745 on one side and attached to the layer of adhesive 715 on the opposite side.

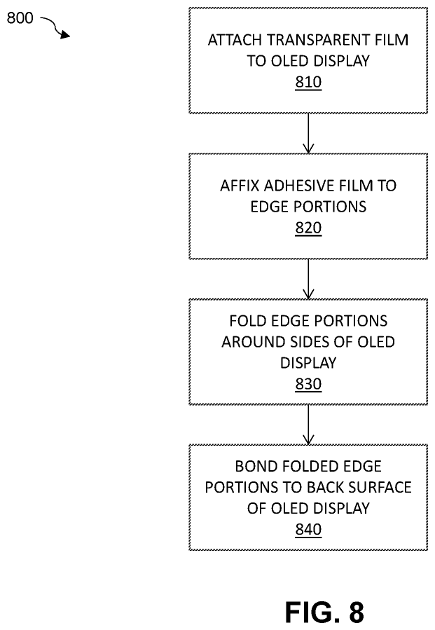

FIG. 8 is a flow chart of a method for fabricating a display. The method 800 includes attaching 810 (e.g., using OCA) a film to a front surface of an OLED display module so that edge portions of the film extend past side surfaces of the OLED display module. Next, an adhesive film is affixed 820 to the edge portions of the film. The edge portions of the film are folded 830 around the side surfaces of the OLED display module and flush (i.e., in line with and contiguous with) with a back surface of the OLED display module. The folded edge portions are then bonded 840 to the back surface of the OLED display module so that the side surfaces of the OLED display module are covered by the film.

The display fabricated using the disclosed method may be affixed between a cover glass and a bezel to become part of a mobile computing device. In a possible embodiment, the film serves a single purpose (e.g., a covering for the sides of the display module) is added to a display module after the display module is fabricated (e.g., laminated). In another possible embodiment the film is a layer of the display module that serves a dual purpose and is added to the display module during its fabrication. For example, a layer of the touch sensor can be enlarged to serve as both a part of the touch sensor for the display and to serve as a side covering when the display is integrated with (i.e., assembly into) the mobile computing device.

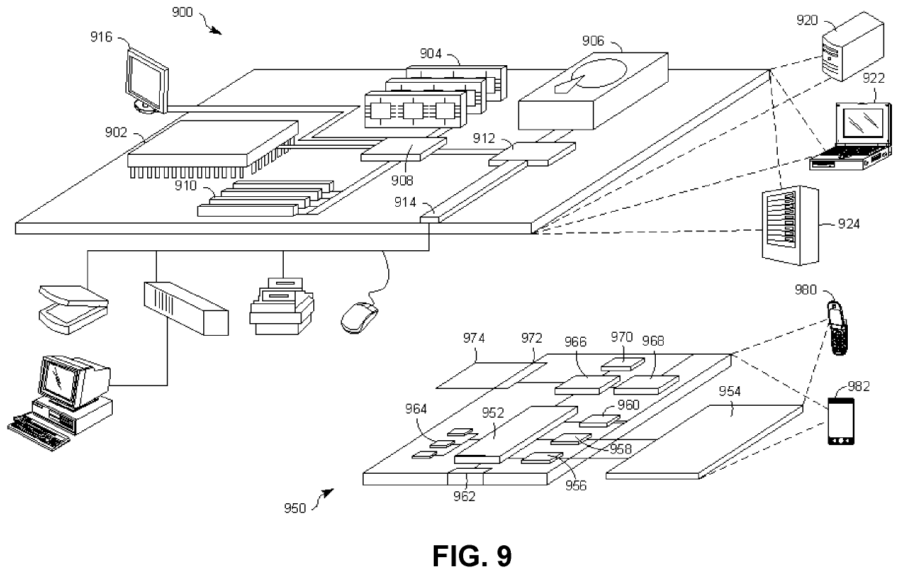

FIG. 9 shows an example of a generic computer device 900 and a generic mobile computer device 950, which may be used with the techniques described here. Computing device 900 is intended to represent various forms of digital computers, such as laptops, desktops, tablets, workstations, personal digital assistants, televisions, servers, blade servers, mainframes, and other appropriate computing devices. Computing device 950 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 900 includes a processor 902, memory 904, a storage device 906, a high-speed interface 908 connecting to memory 904 and high-speed expansion ports 910, and a low speed interface 912 connecting to low speed bus 914 and storage device 906. The processor 902 can be a semiconductor-based processor. The memory 904 can be a semiconductor-based memory. Each of the components 902, 904, 906, 908, 910, and 912, are interconnected using various busses, and may be mounted on a common motherboard or in other manners as appropriate. The processor 902 can process instructions for execution within the computing device 900, including instructions stored in the memory 904 or on the storage device 906 to display graphical information for a GUI on an external input/output device, such as display 916 coupled to high speed interface 908. In other implementations, multiple processors and/or multiple buses may be used, as appropriate, along with multiple memories and types of memory. Also, multiple computing devices 900 may be connected, with each device providing portions of the necessary operations (e.g., as a server bank, a group of blade servers, or a multi-processor system).

The memory 904 stores information within the computing device 900. In one implementation, the memory 904 is a volatile memory unit or units. In another implementation, the memory 904 is a non-volatile memory unit or units. The memory 904 may also be another form of computer-readable medium, such as a magnetic or optical disk.

The storage device 906 is capable of providing mass storage for the computing device 900. In one implementation, the storage device 906 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 904, the storage device 906, or memory on processor 902.

The high speed controller 908 manages bandwidth-intensive operations for the computing device 900, while the low speed controller 912 manages lower bandwidth-intensive operations. Such allocation of functions is exemplary only. In one implementation, the high-speed controller 908 is coupled to memory 904, display 916 (e.g., through a graphics processor or accelerator), and to high-speed expansion ports 910, which may accept various expansion cards (not shown). In the implementation, low-speed controller 912 is coupled to storage device 906 and low-speed expansion port 914. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 900 may be implemented in a number of different forms, as shown in the figure. For example, it may be implemented as a standard server 920, or multiple times in a group of such servers. It may also be implemented as part of a rack server system 924. In addition, it may be implemented in a personal computer such as a laptop computer 922. Alternatively, components from computing device 900 may be combined with other components in a mobile device (not shown), such as device 950. Each of such devices may contain one or more of computing device 900, 950, and an entire system may be made up of multiple computing devices 900, 950 communicating with each other.

Computing device 950 includes a processor 952, memory 964, an input/output device such as a display 954, a communication interface 966, and a transceiver 968, among other components. The device 950 may also be provided with a storage device, such as a microdrive or other device, to provide additional storage. Each of the components 950, 952, 964, 954, 966, and 968, are interconnected using various buses, and several of the components may be mounted on a common motherboard or in other manners as appropriate.

The processor 952 can execute instructions within the computing device 950, including instructions stored in the memory 964. The processor may be implemented as a chipset of chips that include separate and multiple analog and digital processors. The processor may provide, for example, for coordination of the other components of the device 950, such as control of user interfaces, applications run by device 950, and wireless communication by device 950.

Processor 952 may communicate with a user through control interface 958 and display interface 956 coupled to a display 954. The display 954 may be, for example, a TFT LCD (Thin-Film-Transistor Liquid Crystal Display) or an OLED (Organic Light Emitting Diode) display, or other appropriate display technology. The display interface 956 may comprise appropriate circuitry for driving the display 954 to present graphical and other information to a user. The control interface 958 may receive commands from a user and convert them for submission to the processor 952. In addition, an external interface 962 may be provided in communication with processor 952, so as to enable near area communication of device 950 with other devices. External interface 962 may provide, for example, for wired communication in some implementations, or for wireless communication in other implementations, and multiple interfaces may also be used.

The memory 964 stores information within the computing device 950. The memory 964 can be implemented as one or more of a computer-readable medium or media, a volatile memory unit or units, or a non-volatile memory unit or units. Expansion memory 974 may also be provided and connected to device 950 through expansion interface 972, which may include, for example, a SIMM (Single In Line Memory Module) card interface. Such expansion memory 974 may provide extra storage space for device 950, or may also store applications or other information for device 950. Specifically, expansion memory 974 may include instructions to carry out or supplement the processes described above, and may include secure information also. Thus, for example, expansion memory 974 may be provided as a security module for device 950, and may be programmed with instructions that permit secure use of device 950. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 964, expansion memory 974, or memory on processor 952, that may be received, for example, over transceiver 968 or external interface 962.

Device 950 may communicate wirelessly through communication interface 966, which may include digital signal processing circuitry where necessary. Communication interface 966 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 968. In addition, short-range communication may occur, such as using a Bluetooth, WiFi, or other such transceiver (not shown). In addition, GPS (Global Positioning System) receiver module 970 may provide additional navigation- and location-related wireless data to device 950, which may be used as appropriate by applications running on device 950.

Device 950 may also communicate audibly using audio codec 960, which may receive spoken information from a user and convert it to usable digital information. Audio codec 960 may likewise generate audible sound for a user, such as through a speaker, e.g., in a handset of device 950. Such sound may include sound from voice telephone calls, may include recorded sound (e.g., voice messages, music files, etc.) and may also include sound generated by applications operating on device 950.

The computing device 950 may be implemented in a number of different forms, as shown in the figure. For example, it may be implemented as a cellular telephone 980. It may also be implemented as part of a smart phone 982, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

A number of embodiments have been described. Nevertheless, it will be understood that various modifications may be made without departing from the spirit and scope of the invention.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A display comprising:
a cover glass;
a display module that includes multiple layers that are aligned and adhered together to define a plurality of side surfaces; and
a film that includes:
a transparent central portion affixed between the cover glass and a front surface of the display module, and
a plurality of edge portions that are each folded around one of the side surfaces and affixed to a back surface of the display module.

2. The display according to claim 1, wherein the display module includes an organic light emitting diode (OLED) display and a touch sensor.

3. The display according to claim 1, wherein the cover glass, the display module, and the film, are affixed to a bezel that surrounds the cover glass and the plurality of side surfaces of the display module.

4. The display according to claim 1, wherein each of the edge portions forms a barrier between a side surface of the display module and a gap between the bezel and the cover glass, the barrier impermeable to liquid.

5. The display according to claim 1, wherein each of the edge portions of the film are opaque to block light emitted from an edge of the display module.

6. The display according to claim 1, wherein each edge portion of the film has a trapezoidal shape to prevent adjacent edge portions from overlapping at the back surface of the display module.

7. The display according to claim 1, wherein the film is part of a touch sensor.

8. The display according to claim 1, wherein the plurality of edge portions that are each folded around one of the side surfaces and affixed to the back surface of the OLED module create a compressive stress that prevents the multiple layers of the display module from delaminating.

9. The display according to claim 1, wherein the film is a polyethylene terephthalate (PET) film or a colorless polyimide (CPI) film.

10. A method for fabricating a display, the method comprising:
attaching, using an optically clear adhesive (OCA), a film to a front surface of an organic light emitting diode (OLED) display module so that edge portions of the film extend past side surfaces of the OLED display module;
affixing an adhesive film to the edge portions of the film;
folding the edge portions of the film around the side surfaces of the OLED display module and flush with a back surface of the OLED display module; and
bonding, using the adhesive film, the folded edge portions to the back surface of the OLED display module so that the side surfaces of the OLED display module are covered by the film.

11. The method according to claim 10, further comprising:
shaping the film so that no portions of the edge portions overlap on the back surface of the OLED display module when they are folded.

12. The method according to claim 10, wherein:
the edge portions of the film that cover the side surfaces of the OLED module are colored to prevent light leakage from the side surfaces of the OLED display module.

13. The method according to claim 10, further comprising:
adhering the film to a cover glass so that a transparent central portion of the film is located between the cover glass and the OLED display module.

14. The method according to claim 10, further comprising:
attaching the OLED module to a bezel using a double sided tape between the folded edge portions that are flush with the back surface of the OLED display module and a surface of the bezel

15. The method according to claim 10, wherein the film is part of a touch sensor of the OLED display module.

16. A mobile computing device comprising:
a bezel that defines sides of the mobile computing device;
a cover glass that defines a front surface of the mobile computing device; and
a display module affixed between the cover glass and the bezel, wherein the display includes:
multiple layers that are laminated together to define a front surface, a back surface and side surfaces of the display module, and
a film having a transparent central portion that is affixed between the front surface of the display module and the cover glass and having edge portions that are folded around the side surfaces of the display module and affixed to the back surface of display module.

17. The mobile computing device according to claim 16, wherein the multiple layers include an organic light emitting diode (OLED) display and a touch sensor.

18. The mobile computing device according to claim 16, wherein the bezel and the cover glass define a gap and wherein the edge portions of the film block liquids or debris that enter the gap from reaching the side surfaces of the multiple layers.

19. The mobile computing device according to claim 16, wherein the edge portions of the film are opaque to block light emitted from the side surfaces of the multiple layers.

20. The mobile computing device according to claim 16, the edge portions of the film provide a compressive force that prevents the multiple layers from delaminating when the mobile computing device experiences an impact.

21. A display comprising:
an organic light emitting diode (OLED) display module;
a film attached a front surface of the OLED display module using an optically clear adhesive (OCS), the film having edge portions that extend past side surfaces of the OLED display module, wherein the edge portions of the film are folded around the side surfaces of the OLED display module and are bonded flush with a back surface of the OLED display module using an adhesive film affixed to the edge portions.

22. The display according to claim 21, wherein no portions of the edge portions overlap on the back surface of the OLED display module.

23. The display according to claim 21, wherein the edge portions of the film that cover the side surfaces of the OLED module are colored to prevent light leakage from the side surface of the OLED display module.

24. The display according to claim 21, further comprising:
a cover glass that is adhered to the film so that a transparent central portion of the film is located between the cover glass and the OLED display module.

25. The display according to claim 21, further comprising:
a bezel that is attached to the OLED module using double sided tape between the portions of the edge portions that are flush with the back surface of the OLED module and a surface of the bezel.

26. the display according to claim 21, wherein the film is part of a touch sensor of the OLED display module.
